(19) United States
(12) Patent Application Publication
(10) Pub. No.: US 2008/0273567 A1
(43) Pub. Date: Nov. 6, 2008

(54) HYBRID WAVEGUIDE SYSTEMS AND RELATED METHODS

(76) Inventors: Amnon YARIV, Pasadena, CA (US); Xiankai SUN, Pasadena, CA (US)

Correspondence Address: Steinfl & Bruno, 301 N Lake Ave Ste 810, Pasadena, CA, 91101, US

(21) Appl. No.: 12/110,310

(22) Filed: Apr. 26, 2008

Related U.S. Application Data
(60) Provisional application No. 60/927,258, filed on May 2, 2007.

(51) Int. Cl. H01S 5/026; H01L 31/0336; G02B 6/10

(52) U.S. Cl. 372/50.1; 385/131; 257/184; 257/E31.005

(57) ABSTRACT

A III-V semiconductor waveguide is coupled with a Si waveguide to form a hybrid structure. Spatial location of the optical mode (or supermode) of the hybrid structure is controlled by controlling at least one between the geometry and the refractive index of the structure, e.g., varying width of the Si waveguide. Control of such spatial location allows location of the optical mode either almost entirely in the III-V semiconductor waveguide or almost entirely in the Si waveguide, thus allowing various optical arrangements to be obtained according to the location of the optical mode and the proprieties of the waveguides. For example, if the III-V semiconductor waveguide is amplifying and is provided with a highly reflective mirror at one end, the Si waveguide is provided with a partially reflective mirror at the other end, the optical mode is almost entirely located in the gain region of the III-V semiconductor waveguide, and is also almost entirely located in the coupling region of the Si waveguide, a resonator for laser oscillation is obtained.

### CROSS-REFERENCE TO RELATED APPLICATIONS

This application claims priority to U.S. Provisional Application 60/927,258 filed on May 2, 2007 for “Supermode Si/III-V Hybrid Lasers, Optical Amplifiers and Modulators: A Proposal and Analysis” by Amnon Yariv, the contents of which are incorporated herein by reference in their entirety.

### FIELD

The present disclosure relates to optoelectronic integrated circuits and integrated optics. In particular, it relates to waveguide systems and related methods comprising two or more waveguides. More in particular, it relates to hybrid waveguide systems and related methods.

### BACKGROUND

The realization of optical lasers and devices utilizing silicon as the lasing medium remains elusive in optical communications research. A first recent approach, described in O. Boyraz and B. Jalali, “Demonstration of a silicon Raman laser,” Optics Express 12, 5269-5273 (2004), employs Raman oscillation in silicon (Si). A second recent approach, shown in A. W. Fang, H. Park, O. Cohen, R. Jones, M. J. Paniccia and J. E. Bower, “Electrically pumped hybrid AlGaInAs-silicon evanescent laser,” Optics Express 14, 9203-9210 (2006), describes a hybrid AlGaInAs—Si evanescent laser and will be described later with reference to FIG. 2.

Mathematical modelization of waveguide systems is known in the art. FIG. 1 shows a coupled system of two waveguides (10), (20). The eigenmodes of the coupled system are called supermodes (see A. Yariv, in Optical Electronics in Modern Communications, Oxford Univ. Press, New York, 1997, pp. 526-531, incorporated herein by reference, or E. Kapon, J. Katz, and A. Yariv, “Supermode analysis of phase-locked arrays of semiconductor lasers,” Optics Letters 9, 125-127 (1984), also incorporated herein by reference), Eₒ and Eₑ (where “o” stands for odd and “e” stands for even), in accordance with a modelization where (x, y) dependency of the supermode is a linear combination of the modes of the separate (uncoupled) waveguides (10), (20), which combination travels with a single phase velocity. Such dependency can be written as:

E(x,y,z)=[au₁(x,y)+bu₂(x,y)]e^{iβz}. (1)

Each of the supermodes Eₒ and Eₑ is determined by the ratio (a/b) and by a propagation constant β. As shown in the A. Yariv publication cited above, these modes are given by:

$$\begin{matrix}{E}_{o} ( z ) = {\vert \begin{matrix}b \\ a\end{matrix} \vert}_{o} {e}^{- {iβ}_{o} z} = \vert \begin{matrix}\frac{i {κ}^{*}}{δ + S} \\ 1\end{matrix} \vert {e}^{- i ( \overline{β} - S ) z} & ( 2 ) \\ {E}_{e} ( z ) = {\vert \begin{matrix}b \\ a\end{matrix} \vert}_{e} {e}^{- {iβ}_{e} z} = \vert \begin{matrix}\frac{i {κ}^{*}}{δ - S} \\ 1\end{matrix} \vert {e}^{- i ( \overline{β} - S ) z} & ( 3 ) \\ where \\ 2 \overline{β} = {β}_{1} + {β}_{2} , 2 δ = {β}_{2} - {β}_{1} , S = \sqrt{{δ}^{2} + {κ}^{2}} , & ( 4 )\end{matrix}$$

and κ is given by an overlap integral involving u₁ and u₂, and the index perturbation function.

Of particular interest are the three limiting values: (a) δ<0 while |δ|>>|κ|, (b) δ=0, and (c) δ>0 while δ>>|κ|. The corresponding modes are respectively:

$$\begin{matrix}( a ) δ < 0 ( {β}_{1} > {β}_{2} ) , \vert δ \vert >> \vert κ\vert \\ {\vert \begin{matrix}b \\ a\end{matrix} \vert}_{o} \to \vert \begin{matrix}- 1 \\ ɛ\end{matrix} \vert , {\vert \begin{matrix}b \\ a\end{matrix} \vert}_{e} \to \vert \begin{matrix}ɛ \\ 1\end{matrix} \vert & ( 5 ) \\ where ɛ = \vert \frac{κ}{2 δ} \vert << 1 \\ ( b ) δ = 0 ( {β}_{1} = {β}_{2} ) \\ {\vert \begin{matrix}b \\ a\end{matrix} \vert}_{o} \to \vert \begin{matrix}- 1 \\ 1\end{matrix} \vert , {\vert \begin{matrix}b \\ a\end{matrix} \vert}_{e} \to \vert \begin{matrix}1 \\ 1\end{matrix} \vert & ( 6 ) \\ ( c ) δ > 0 ( {β}_{1} < {β}_{2} ) , δ >> \vert κ\vert \\ {\vert \begin{matrix}b \\ a\end{matrix} \vert}_{o} \to \vert \begin{matrix}- ɛ \\ 1\end{matrix} \vert , {\vert \begin{matrix}b \\ a\end{matrix} \vert}_{e} \to \vert \begin{matrix}1 \\ ɛ\end{matrix} \vert \\ where ɛ = \vert \frac{κ}{2 δ} \vert << 1 & ( 7 )\end{matrix}$$

The corresponding supermode profiles are shown in FIG. 1. The subscripts designation “even” (e) and “odd” (o) is derived from the modal symmetry at the phase-matched, δ=0, condition.

Each of the supermodes Eₒ and Eₑ represents the status of the optical modal energy of the waveguide system of FIG. 1. As shown in FIG. 1, when δ<0, the optical mode of the waveguide system can be represented either by a supermode Eₑ substantially located in waveguide (10) or a supermode Eₒ substantially located in waveguide (20). Similarly, when δ>0, the optical mode of the waveguide system can be represented either by a supermode Eₑ substantially located in waveguide (20) or a supermode Eₒ substantially located in waveguide (10). On the other hand, when δ=0, the optical mode of the waveguide system can be represented by a supermode Eₑ substantially equally distributed between the waveguide (10) and the waveguide (20) or a supermode Eₒ also substantially equally distributed between the two waveguides.

FIG. 2 shows a prior art arrangement, also shown in U.S. Pub. App. 2008/0002929, which is incorporated herein by reference in its entirety. In the side view of FIG. 2, a III-V material amplifying slab (21) is coupled with a Si (silicon) waveguide (22) located above a SiO₂ layer (23) of a SOI substrate, to form an evanescent hybrid laser. In particular, the optical mode (24) is guided in waveguide (22) but is amplified due to the penetration of its small evanescent tail (25) into the gain region of current-pumped slab (21).

The reliance on the small evanescent tail penetrating into the gain region is a major handicap of this approach since it leads to a small modal gain thus requiring longer lasers and results in low efficiencies.

### SUMMARY

According to a first aspect of the present disclosure, a hybrid waveguide system is provided, comprising: an active semiconductor material configured to exhibit a waveguide behavior, and a silicon waveguide coupled with the active semiconductor material, wherein the hybrid waveguide system has a transversal extension and wherein geometry and/or refractive index of at least one between the active semiconductor material and the silicon waveguide is varied along the transversal extension of the hybrid waveguide system to vary spatial location of optical modal energy of the hybrid waveguide system between a spatial location substantially entirely in one of the active semiconductor material or silicon waveguide and a spatial location substantially entirely in the other of the active semiconductor material or silicon waveguide.

According to a second aspect of the present disclosure, a method for operating a hybrid waveguide system comprising an active semiconductor material and a silicon waveguide coupled with the semiconductor material is provided, the method comprising: configuring the active semiconductor material to operate as a waveguide; controlling optical modal energy of the hybrid waveguide system to spatially locate the optical modal energy substantially entirely in the active semiconductor material in a first transversal region of the hybrid waveguide system and to spatially locate the optical modal energy substantially entirely in the silicon waveguide in a second transversal region of the hybrid waveguide system.

According to a third aspect of the present disclosure, a method for controlling spatial location of optical modal power is provided, comprising: providing an active semiconductor material in which the optical modal power is adapted to be spatially located; providing a silicon waveguide coupled with the active semiconductor material, in which silicon waveguide the optical modal power is adapted to be spatially located; providing a geometry and/or refractive index variation in at least one between the active semiconductor material and the silicon waveguide to switch the spatial location of the optical modal power from one between the active semiconductor material and the silicon waveguide to the other between the active semiconductor material and the silicon waveguide.

Further embodiments of the present disclosure are shown in the written specification, drawings and claims of this application.

The approach described in accordance with the present disclosure eliminates, in principle, the basic compromise inherent in the evanescent laser design since the full optical modal power, rather than the evanescent tail, is available for amplification. This results in a larger modal gain and increased output coupling efficiency. In other words, without control of the geometry and/or refractive index of the waveguides, e.g. width of one waveguide, there is a tradeoff between the modal gain and the output coupling efficiency. In the prior art realization shown in FIG. 2, the modal intensity where the gain has its peak is low. Stated differently, if the gain spatial distribution does not overlap with the modal intensity distribution, the resulting modal gain is small.

### BRIEF DESCRIPTION OF THE FIGURES

FIG. 1, already discussed above, is a schematic diagram showing supermodes of a coupled waveguide system.

FIG. 2, already discussed above, is a cross-sectional view of a prior art laser based on an evanescent coupling concept.

FIG. 3 is a cross-sectional view of a hybrid waveguide system according to an embodiment of the present disclosure.

FIGS. 4(a) and 4(b) show cross-sectional and top views, respectively, of a hybrid waveguide system according to a further embodiment of the present disclosure.

FIGS. 5(a) and 5(b) show cross-sectional and top views, respectively, of a hybrid waveguide system according to yet another embodiment of the present disclosure.

FIGS. 6(a) and 6(b) are cross-sectional and top views showing a further embodiment of a laser resonator in accordance with the present disclosure.

FIGS. 7 and 8 are waveforms showing variation of δ with respect to z direction in the embodiments of FIGS. 4 and 5, respectively.

FIGS. 9(a) and 9(b) are cross-sectional and top views showing an embodiment of the present disclosure where a Bragg reflector is provided.

FIGS. 10(a) and 10(b) are cross-sectional and top views of an embodiment of the present disclosure operating as a photodetector.

FIGS. 11(a) and 11(b) are cross-sectional and top views of an embodiment of the present disclosure making use of a ring-shaped waveguide, allowing operation as a modulator or a laser.

FIGS. 12(a) and 12(b) are cross-sectional and top views of a coupled resonator optical waveguide obtained by way of the teachings of the present disclosure.

FIG. 13 is a schematic modular arrangement where the teachings of the present disclosure are combined to show an integrated optoelectronic circuit.

### DETAILED DESCRIPTION

In accordance with the present disclosure, a waveguide system is provided, comprising an active semiconductor material or medium having a waveguide behavior coupled with a Si (silicon) waveguide. An active semiconductor material is a material generating and amplifying light in response to a stimulation, such as optical and/or electrical pumping. A waveguide behavior can be defined as the property of confining and guiding optical waves. In the main embodiment of the present disclosure the active semiconductor material having a waveguide behavior can be a III-V semiconductor waveguide. III-V is intended to mean III-V semiconductor materials such as InP, AlGaInAs and/or InP/InGaAsP and similar materials. However, embodiments can be provided where the semiconductor material is a II-VI semiconductor (e.g., cadmium selenide) waveguide. Throughout the present disclosure, coupling between the active semiconductor material and the Si waveguide will refer to a spatial arrangement of the active material and the Si waveguide with respect to each other, and will be intended as contact or very close proximity.

In the waveguide system of the present disclosure, optical modal power or energy (the two terms will be used interchangeably in this disclosure) is controlled by varying the spatial location of the supermode Eₑ or supermode Eₒ between the waveguides of the waveguide system. In other words, according to one of the embodiments of the present disclosure, a waveguide system is provided where a first transversal portion of the waveguide system is characterized by the optical modal power of the system substantially located in the amplifying material, a second transversal portion of the waveguide system is characterized by the optical modal power of the system substantially distributed between the amplifying material and the Si waveguide, and a third transversal portion of the waveguide system is characterized by the optical modal power of the system substantially located in the Si waveguide. In particular, optical modal power can be confined to any of the two waveguides. Of course, alternative and different configurations are also possible, all having in common the feature that spatial location of the optical modal power or energy of the waveguide system is varied along the transversal or z direction of the waveguide system.

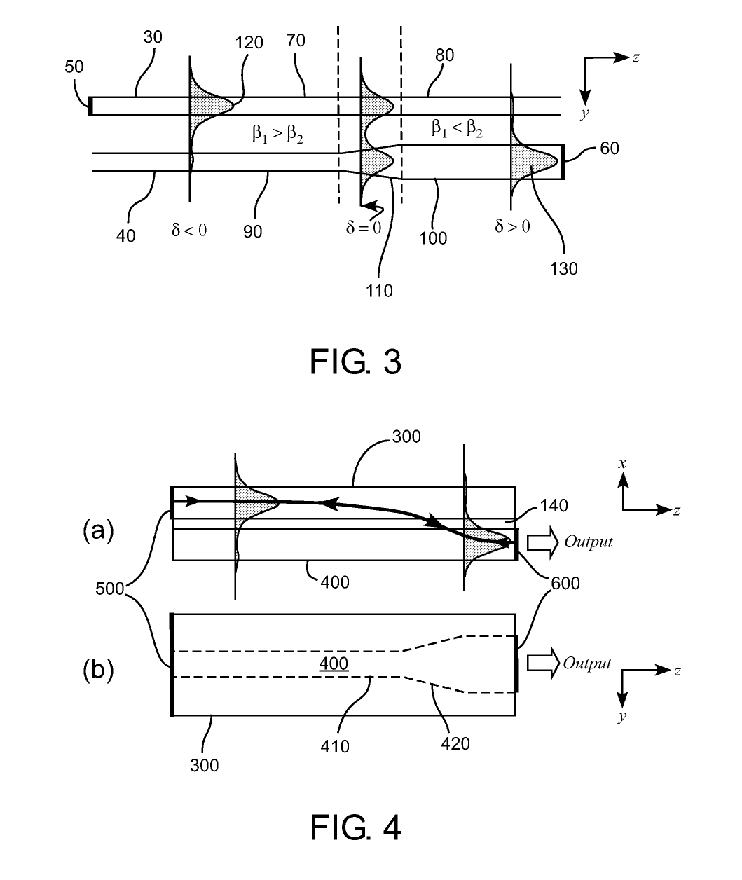

FIG. 3 shows a cross-sectional side view of a conceptual representation of one embodiment of the present disclosure, where a waveguide system acting as a laser resonator is shown. In particular, a hybrid waveguide system comprised of a III-V material semiconductor waveguide (30) and a Si waveguide (40) is shown. In order to act as a resonator, waveguide (30) comprises a highly reflective facet (50), and waveguide (40) comprises a partially reflective output facet (60), e.g. a partial mirror. Location of electrical contacts (not shown) on the waveguide (30) and pumping current intensity through the contacts by way of an electrical pump circuit (not shown) defines an amplifying region (70) and an absorbing region (80) in the waveguide (30).

In the embodiment of FIG. 3, control of the spatial location of the optical modal power is obtained by controlling the variable

$$δ = \frac{{β}_{2} - {β}_{1}}{2}$$

of equation (4) above, where β₁ and β₂ are the propagation constants of the modes of the separate (uncoupled) waveguide (30) and waveguide (40), respectively. In particular, δ will be <0 (β₁>β₂) along the amplifying region (70) of the waveguide (30) and δ will be >0 (β₁<β₂) along the absorbing region (80) of the waveguide (30). Variation of δ along the transversal direction of the waveguide system is obtained by varying the geometries and/or refractive indices of the waveguide (30) and/or the waveguide (40). By way of example, FIG. 3 shows a waveguide (40) comprising a region (90) having a first width, a region (100) having a second width larger than the first width, and a third region (110) having a width variable between the first width and the second width. δ changes with the change of the width of waveguide (40) because the propagation constant β₂ depends on the width of the waveguide (40).

In the embodiment shown in FIG. 3, the first width of region (90) is selected to keep the optical modal power of the waveguide system in the waveguide (30), while the tapered region (110) and the second width of region (100) are selected to switch the spatial location of the optical modal power of the waveguide system from waveguide (30) to waveguide (40), as shown in FIG. 3.

Following the modal field of FIG. 3 through one round trip, the mode starts propagating from left to right in the left region of waveguide (30) where it is amplified. The mode then enters a region corresponding to the tapered region (110) of waveguide (40), where the optical modal power is switched from waveguide (30) to waveguide (40). At a certain point, the mode will be substantially evenly distributed between waveguide (30) and waveguide (40). The mode is then switched to waveguide (40) and is then partially reflected by partially reflective facet or mirror (60). The reflected field retraces its path and is then reflected from highly reflective facet (50), thus completing the round trip.

As shown in FIG. 3, the peak modal field (120) is spatially located inside the amplifying region (70) of waveguide (30). Therefore, a substantially maximum gain can be obtained in the amplifying region (70). Such substantially maximum gain is in sharp contrast with the prior art evanescent tail inducing the amplifying transitions in the gain (III-V) region of the prior art shown in FIG. 2.

Stated with different words, the present disclosure allows to obtain a large overlap between the gain spatial distribution of the III-V material and the optical modal intensity. Once the injected current of the III-V medium is above the transparency value, the III-V semiconductor material becomes amplifying and is able to provide gain. Transparency current is defined as the value of current at which the III-V medium is transparent to the wavelength of interest. The III-V medium is absorbing with injected current below this value, and amplifying with injected current above this value. The modal gain (i.e., the exponential gain constant experienced by the propagating laser mode) depends on and is proportional to the overlap integral between the spatial distribution of the gain and that of the mode intensity. See, for example, A. Yariv, Optical Electronics in Modern Communications (5^{th} ed.) pp. 573-575. In other words, if the quantum wells (i.e., the regions providing the gain in a III-V material) are placed at a position A where the field intensity is twice as large as in another position B, then for the same excess current (above the transparency value), the modal gain in case A is twice as large. Therefore, generally speaking, the modal distribution should be designed so as to overlap the gain distribution as much as possible.

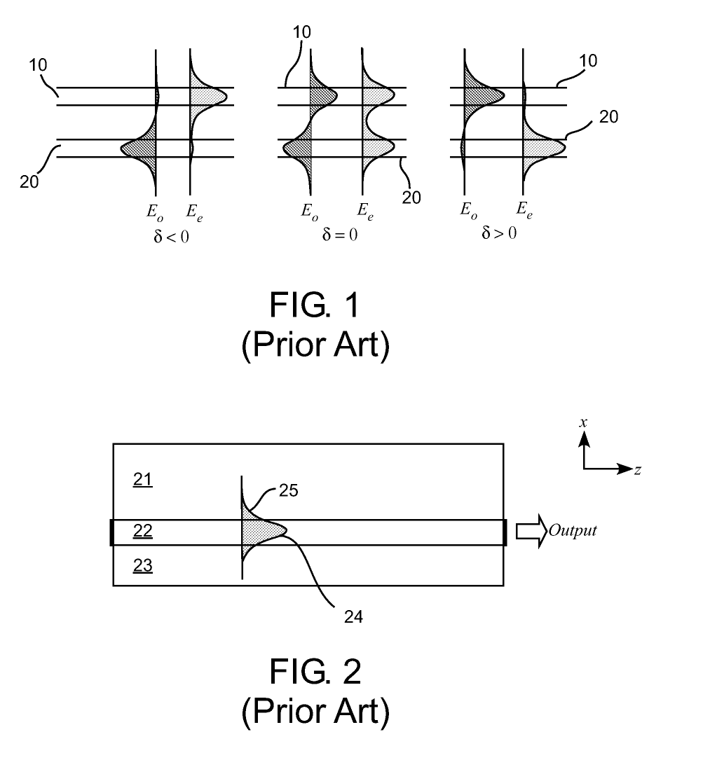

Similarly, the full field (130) is present in the right region of waveguide (40) ready for coupling to other parts of the Si chip onto which waveguide (40) can be made, or coupling into an output fiber for chip transport. The odd mode Eₒ is prevented from lasing since, according to FIG. 1, it traverses the absorbing region (80) of waveguide (30).

FIG. 4 shows a representation of an embodiment conceptually identical to the embodiment of FIG. 3, where section (a) shows a cross-sectional side view of the waveguide system of the present disclosure, and section (b) shows a top view of the system. As shown in FIG. 4(a), III-V waveguide (300) and Si waveguide (400) can be separated by a silica (SiO₂) layer (140). The thin SiO₂ layer shown in the embodiment of FIG. 4(a) assists in bonding the III-V waveguide and Si waveguide together to form the coupled waveguide system shown in FIG. 4(a). Alternatives are, for example, low-refractive-index polymers which can be used for wafer bonding purposes. As shown in FIG. 4(b), waveguide (300) is located above and covers waveguide (400). Waveguide (400) extends below waveguide (300) and substantially along the central transversal region of waveguide (300). Waveguide (400) comprises a main body (410) substantially corresponding to region (90) of FIG. 3 and a taper (420) substantially corresponding to region (110) of FIG. 3.

According to an embodiment of this disclosure, the tapered region (110) of FIG. 3 or the tapered region (420) of FIG. 4 is an adiabatic tapered region, meaning that the change in waveguide geometry and/or refractive index along the transversal direction, herein the width of waveguide (40) of FIG. 3 or waveguide (400) of FIG. 4, does not excite modes which are different from the mode of interest. The person skilled in the art will understand that different taper design schemes (e.g., lateral, vertical, and combined tapers) can be employed for this purpose. Common fabrication techniques for the taper structures include etching and selective growth.

Therefore, it is possible, by proper choice of the width of the Si waveguide, to direct the optical modal power to the amplifying III-V waveguide or to the Si waveguide, thereby avoiding the degraded performance which results from the reliance on the evanescent field. This can be realized by adiabatically changing the geometry of the system, e.g., by adiabatically varying the width of the Si waveguide. The term “geometry” is here intended to mean the physical and/or spatial and/or dimensional arrangement of the system. By way of example and not of limitation, the III-V waveguide can employ an identical layer structure to that used in the prior art arrangement of FIG. 2, the only difference being that a 3.34-μm-wide mesa was etched in the center to form a waveguide. Also, a 0.05-μm-thick silica layer was introduced between the III-V waveguide and the Si waveguide. By way of further example, the Si waveguide can have a height H=0.8 μm.

The embodiments of FIGS. 3, 4 and 6 show laser resonator arrangements. However, the same principle of spatial switching of the optical modal power can be used to achieve other functions. For example, to make an optical amplifier, the input optical modal power can be switched from a wide (δ>0) Si waveguide to a III-V waveguide section (δ<0) for amplification and back again to the wide (δ>0) Si waveguide. The same geometry can also be used to make an absorption modulator, a current controlled phase modulator, a current controlled amplitude modulator, and so on.

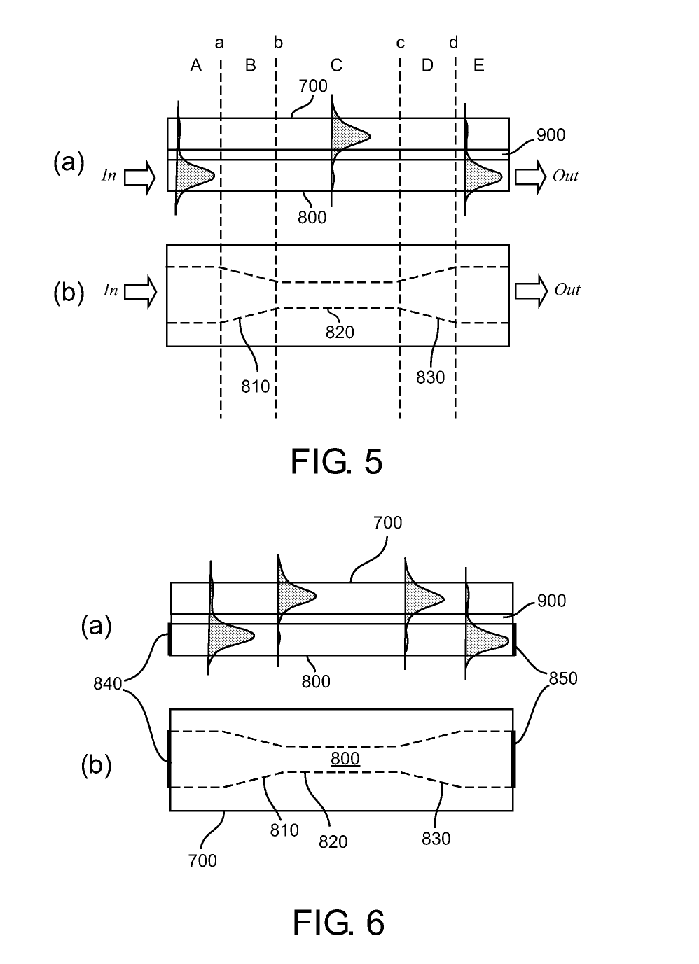

In this respect, FIG. 5 shows a representation of an optical amplifier and/or modulator. FIG. 5(a) shows a cross-sectional side view of a III-V waveguide (700) and a Si waveguide (800) separated by a SiO₂ layer (900). FIG. 5(b) shows a top view of the system, where waveguide (700) is located above and covers waveguide (800). Waveguide (800) extends below waveguide (700) and substantially along the central transversal region of waveguide (700). Waveguide (800) comprises a first tapered region (810), a central body (820) and a second tapered region (830). As schematically represented in FIGS. 5(a) and 5(b), five different regions (A through E) can be defined. In section A, the light is coupled into the Si waveguide with high coupling efficiency (due to minimal mismatch of spatial modal distributions). In section B (corresponding to the first tapered region (810) of the waveguide (800)), the mode gradually completes its transformation so as to have most of the optical modal power concentrated in the upper waveguide (700) at the end of the tapered region (810) (plane b). In section C, since the mode propagates with most of its energy in the upper waveguide (700), the function of the upper medium (amplification or modulation) can be fully utilized. After operation in section C, the mode gradually transforms back in section D (corresponding to the second tapered region (830) of the waveguide (800)) so as to move most of the optical modal power to the lower Si waveguide (800). In section E, after transformation, the mode is ready for coupling to the outside (again with high coupling efficiency).

FIG. 6 shows an embodiment similar to the one shown in FIG. 5, where a highly reflective mirror (840) is located at a first end of the Si waveguide (800) and a partially reflective mirror (850) is located at the other end of the Si waveguide (800). The structure thus formed behaves as a laser resonator.

While in the above embodiments control of the spatial location of the optical modal power is obtained by varying the width of the Si waveguide, the person skilled in the art will understand that such control can be obtained also through variation of the width of the III-V waveguide or any other variation of the geometry (e.g., variation of the height) and/or the refractive index of one or two of the waveguides.

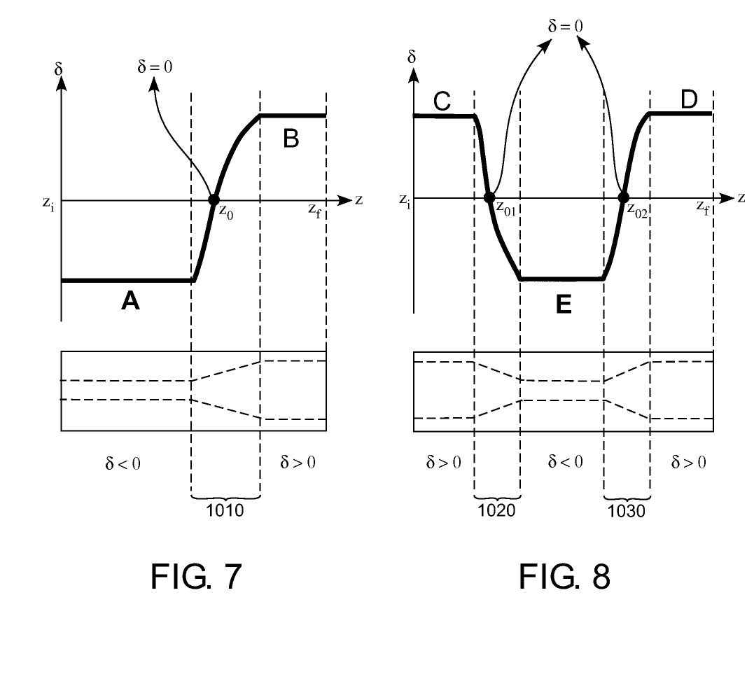

FIGS. 7 and 8 show the evolution of δ along the propagation (transversal) direction or z direction for the embodiments of FIGS. 4 and 5, respectively. When the geometry of the waveguide (here the width of the Si waveguide) is fixed, the value of δ is constant, as indicated in sections A and B of FIG. 7 and sections C, D, and E of FIG. 8. In the tapered regions (1010), (1020), (1030), varied waveguide geometry results in changing δ, with

$$δ = \frac{{β}_{2} - {β}_{1}}{2} ,$$

where β₁ is fixed, but β₂=β₂(z) varies with the change of waveguide geometry. In the tapered region (1010), a continuous curve connects sections A and B. Similarly, continuous curves connect sections C and E, and sections E and D in the tapered regions (1020) and (1030), respectively. The points where these curves intersect with the z axes are referred to as the synchronism points, and correspond to the condition δ=0. Generally, the synchronism points correspond to the condition where optical modal power is evenly distributed between the two constituent waveguides.

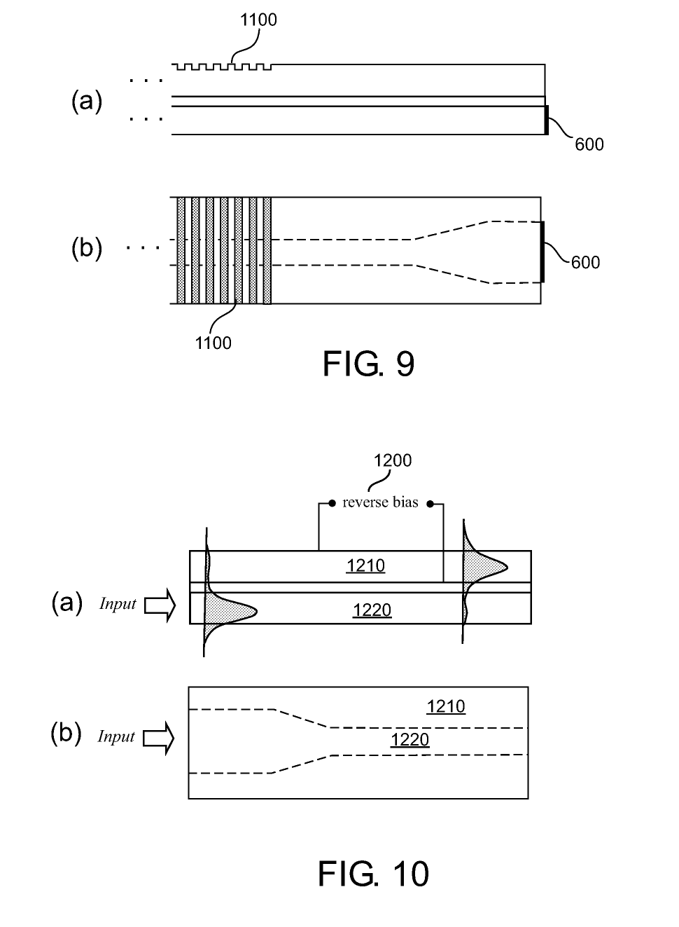

FIG. 9 shows a further embodiment of the present disclosure, where the embodiment shown in FIGS. 4(a) and 4(b) has been modified through provision of a periodic corrugation or Bragg grating (1100) on the III-V material. In particular, the Bragg grating acts as a Bragg reflector and can be used for the purpose of providing high reflection. The additional advantage of such embodiment is that the Bragg reflector only highly reflects light within a specific wavelength range. In this respect, the Bragg reflector acts as an integrated wavelength filter which can provide strong feedback to the optical waves with wavelength of interest inside the laser resonator.

FIGS. 10(a) and 10(b) show a further embodiment of the present disclosure where a reverse voltage bias (1200) is provided to the III-V waveguide (1210) coupled to the Si waveguide (1220). According to this embodiment, light is first highly efficiently coupled into the Si waveguide (1220). Then, by adiabatic taper, the mode is transformed such that most of the optical power shifts to the upper waveguide (1210) which, under the reverse voltage bias (1200), is highly absorbing. The absorbed light excites extra electron-hole pairs across the p-n junction contributing to the conductivity, which reflects in the change of the current in the electric circuit. Therefore, the coupled waveguide system of FIG. 10 works as a photodetector.

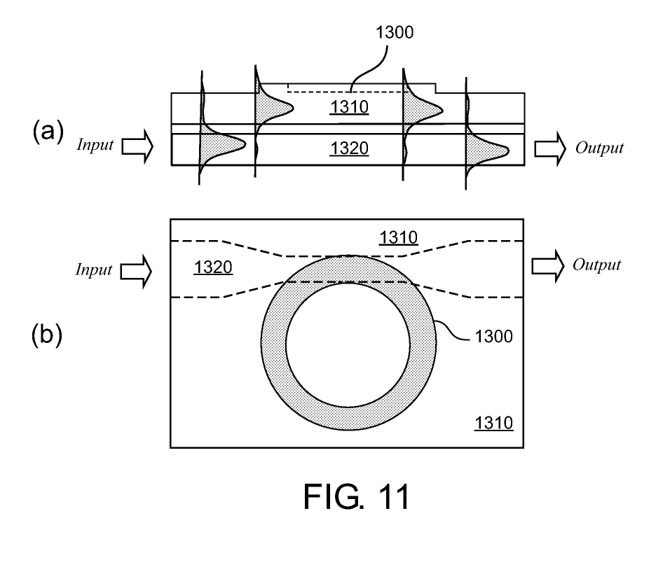

FIGS. 11(a) and 11(b) show a further embodiment where a ring-shaped waveguide (1300) acting as a ring resonator is fabricated in the upper III-V medium (1310). Such arrangement can operate both as a modulator and as a laser.

To obtain operation as a modulator, light is first highly efficiently coupled into the Si waveguide (1320). Then, by way of the adiabatic taper, the mode is transformed such that most of its power shifts to the upper III-V medium (1310) in which the ring-shaped waveguide (1300) is fabricated. The mode circulates in this ring resonator while experiencing modulation. The modulated light is coupled back to the Si waveguide (1320) by a second adiabatic taper, and then to the outside.

Laser operation of the embodiment of FIG. 11 can be obtained by providing a highly reflective structure (e.g., an as-cleaved facet with coating or a Bragg grating) at one end of the Si waveguide (1320), and a partially reflective output facet (e.g., an as-cleaved facet) at the other end of the Si waveguide (1320), similarly to that shown in the previous embodiments. If the mode circulating in the ring has enough gain to compensate the loss, then laser emission will come out of the partially reflective output facet.

In the above two applications of FIG. 11, the person skilled in the art will understand that the ring (1300) can be replaced by other types of resonators that provide frequency selection, such as a disk resonator or a Bragg resonator.

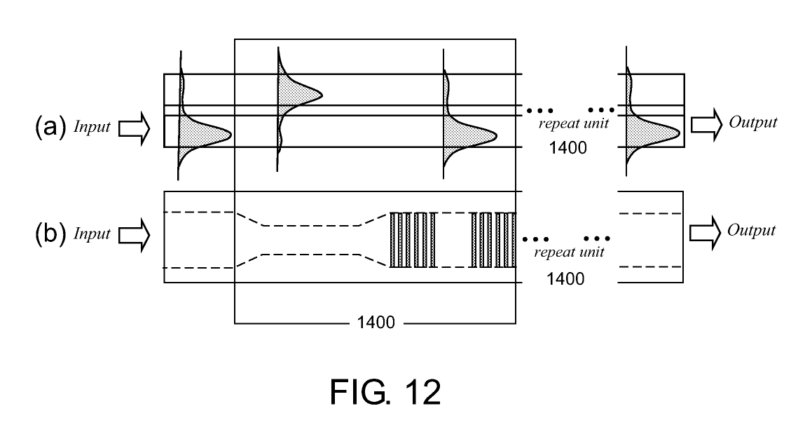

FIGS. 12(a) and 12(b) show a further embodiment of the present disclosure, where a coupled resonator optical waveguide (CROW) is obtained. CROW structures as such are known for slow light applications due to the slow group velocity of their modes. However, in a chain of passive resonators, the light decays as it propagates. The embodiment of FIG. 12 overcomes such drawback by incorporating in each unit (1400) of the CROW a gain section in accordance with the present disclosure, where optical modal power is shifted from the Si waveguide to the III-V medium and then back to the Si waveguide, so that a long CROW can be realized.

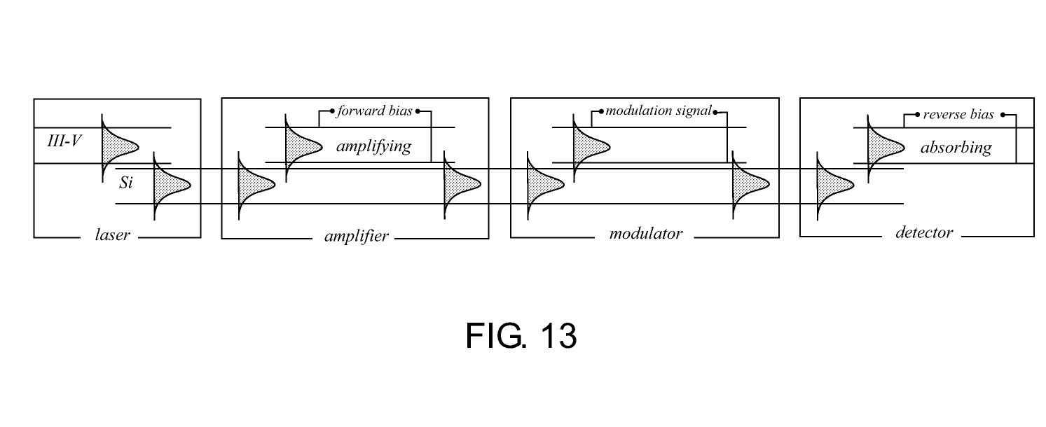

FIG. 13 is a schematic figure, where the teachings of the present disclosure are combined to show an integrated optoelectronic circuit comprised of elements such as lasers, amplifiers, modulators, and detectors in accordance with the present disclosure. In other words, devices with different functions can be integrated on a Si platform to form large-scale, high-efficiency hybrid optoelectronic circuitry. The light transportation from one module to another can be on-chip by way of the Si waveguide or chip-to-chip by way of optical fiber.

Accordingly, what has been shown are hybrid waveguide systems and methods. While these hybrid waveguide systems and methods have been described by means of specific embodiments and applications thereof, it is understood that numerous modifications and variations could be made thereto by those skilled in the art without departing from the spirit and scope of the disclosure. It is therefore to be understood that within the scope of the claims, the disclosure may be practiced otherwise than as specifically described herein.

What is claimed is:

1. A hybrid waveguide system comprising:
an active semiconductor material configured to exhibit a waveguide behavior, and
a silicon waveguide coupled with the active semiconductor material, wherein the hybrid waveguide system has a transversal extension and wherein geometry and/or refractive index of at least one between the active semiconductor material and the silicon waveguide is varied along the transversal extension of the hybrid waveguide system to vary spatial location of optical modal energy of the hybrid waveguide system between a spatial location substantially entirely in one of the active semiconductor material or silicon waveguide and a spatial location substantially entirely in the other of the active semiconductor material or silicon waveguide.

2. The hybrid waveguide system of claim 1, wherein the active semiconductor material configured to exhibit a waveguide behavior is a III-V semiconductor waveguide.

3. The hybrid waveguide system of claim 1, wherein the geometry of at least one between the active semiconductor material and the silicon waveguide is varied along the transversal extension of the hybrid waveguide system by varying width of the silicon waveguide along the transversal extension of the hybrid waveguide.

4. The hybrid waveguide system of claim 2, wherein the silicon waveguide comprises a first transversal region having a first width, a second transversal region having a second width, and a transversally tapered region between the first transversal region and the second transversal region.

5. The hybrid waveguide system of claim 4, configured to operate as a laser resonator.

6. The hybrid waveguide system configured to operate as a laser resonator of claim 5, wherein the III-V semiconductor waveguide comprises a highly reflective mirror on one side of the system and the Si waveguide comprises a partially reflective mirror on the other side of the system.

7. The hybrid waveguide system configured to operate as a laser resonator of claim 6, wherein the highly reflective mirror is a Bragg reflector.

8. A photodetector comprising the hybrid waveguide system of claim 1, wherein a reverse voltage bias is applied to the active semiconductor material.

9. The hybrid waveguide system of claim 2, wherein the silicon waveguide comprises a substantially central region having a first width, two end regions having a second width and two transversally tapered regions connecting each of the two end regions with the substantially central region.

10. The hybrid waveguide system of claim 9, configured to operate as a laser resonator, a coupled resonator optical waveguide, an optical amplifier, or optical modulator.

11. The hybrid waveguide system of claim 9, further comprising a ring-shaped waveguide fabricated in the III-V semiconductor material, the ring-shaped waveguide acting as a ring resonator.

12. An optoelectronic component comprising the hybrid waveguide system of claim 1.

13. An integrated optoelectronic circuit comprising a plurality of optoelectronic components according to claim 12.

14. A method for operating a hybrid waveguide system comprising an active semiconductor material and a silicon waveguide coupled with the semiconductor material, the method comprising:
configuring the active semiconductor material to operate as a waveguide;
controlling optical modal energy of the hybrid waveguide system to spatially locate the optical modal energy substantially entirely in the active semiconductor material in a first transversal region of the hybrid waveguide system and to spatially locate the optical modal energy substantially entirely in the silicon waveguide in a second transversal region of the hybrid waveguide system.

15. The method of claim 14, wherein the first transversal region corresponds to an optical amplification region of the active semiconductor material.

16. The method of claim 14, wherein the second transversal region corresponds to an optical coupling region of the silicon waveguide.

17. A method for controlling spatial location of optical modal power, comprising:
providing an active semiconductor material in which the optical modal power is adapted to be spatially located;
providing a silicon waveguide coupled with the active semiconductor material, in which silicon waveguide the optical modal power is adapted to be spatially located;
providing a geometry and/or refractive index variation in at least one between the active semiconductor material and the silicon waveguide to switch the spatial location of the optical modal power from one between the active semiconductor material and the silicon waveguide to the other between the active semiconductor material and the silicon waveguide.

18. The method for controlling the spatial location of optical modal power of claim 17, wherein at least one instance is present where the optical modal power is equally distributed between the active semiconductor material and the silicon waveguide.
